(19) United States
(12) Patent Application Publication
(10) Pub. No.: US 2026/0186421 A1
(43) Pub. Date: Jul. 2, 2026

(54) METHOD FOR IMPROVING THROUGHPUT OF PACKAGING LITHOGRAPHY AT LOWER RESOLUTIONS

(71) Applicant: Onto Innovation Inc., Wilmington, MA (US)

(72) Inventors: Keith F. Best, Wilmington, MA (US); Jyr Soo, Peabody, MA (US)

(73) Assignee: Onto Innovation Inc., Wilmington, MA (US)

(21) Appl. No.: 19/005,716

(22) Filed: Dec. 30, 2024

(51) Int. Cl. G03F 7/20; G03F 7/00; H01J 37/317

(52) U.S. Cl. CPC G03F 7/2022; G03F 7/2059; G03F 7/70383; H01J 37/3174; H01J 2237/31754; H01J 2237/31755

(57) ABSTRACT

The present application provides a method for improving throughput of lithography at lower resolutions in substrate fabrication. The disclosure utilizes combining photolithography with direct writing lithography in substrate fabrication. The method comprises of, exposing with photolithography equipment circuit patterns on a substrate of at least one-micron resolution and larger in a photoresist, wherein the field size is at least 50 mm by 50 mm; and exposing with direct writing lithography equipment on the substrate circuit patterns less than at least one-micron resolution and smaller.

### TECHNICAL FIELD

The present disclosure is directed to a method of improving throughput of panel lithography at lower resolutions. More particularly, the method involves optimizing the process to maximize efficiency by combining photolithography with direct writing lithography in substrate fabrication.

### BACKGROUND

In semiconductor manufacturing, lithography forms an integral part typically involving transferring of intricate patterns onto substrates, such as a silicon wafer or glass substrates, using light, to fabricate the integrated circuits (ICs). It majorly finds it application in microprocessors, solid-state memories and also in preparing metal nanoparticles, particularly in high-volume manufacturing (HVM) applications. It is pertinent to note that the need to increase throughput while maintaining precision at lower resolutions is useful for next-generation devices with smaller feature sizes. However, achieving both precision and enhanced throughput at lower resolutions has been challenging due to various constraints, such as diffraction limits, overlay accuracy, and resist sensitivity. In the conventional state of art, lithography throughput is improved at lower resolutions either by utilizing multi-patterning, extreme ultraviolet (EUV) lithography, or optimized resist chemistries.

### SUMMARY

One aspect of the present disclosure provides method for improving throughput of lithography at lower resolutions by combining photolithography with direct writing lithography in substrate fabrication. The method comprising of, exposing with photolithography equipment circuit patterns on a substrate of at least one-micron resolution and larger in a photoresist, wherein a field size of the photolithography equipment is at least 50 mm by 50 mm; and exposing with direct writing lithography equipment on the circuit patterns on the substrate less than at least one-micron resolution and smaller.

Another aspect of the disclosure provides a lithography system for improving throughput of lithography at lower resolutions by combining photolithography with direct writing lithography in substrate fabrication comprising photolithography equipment configured to expose a circuit pattern on a substrate of at least one-micron resolution and larger in a photoresist, wherein a field size of the photolithography equipment is at least 50 mm by 50 mm; a plurality of direct writing lithography equipment on the substrate to expose circuit patterns less than at least one-micron resolution and smaller; and a transfer system that passes a substrate from the photolithography equipment to one of the plurality of direct writing lithography equipment.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Additional aspects, features, and/or advantages of examples will be set forth in part in the description which follows and, in part, will be apparent from the description, or may be learned by practice of the disclosure.

### BRIEF DESCRIPTION OF THE DRAWINGS

Non-limiting and non-exhaustive examples are described with reference to the following figures.

FIG. 1 depicts a method for improving throughput of lithography at lower resolutions, in accordance with an embodiment of the disclosure.

FIG. 2 schematically depicts a photolithography equipment, in accordance with an embodiment of the disclosure.

FIG. 3 schematically depicts an electron beam lithography equipment, in accordance with an embodiment of the disclosure.

FIG. 4 schematically depicts a combined hybrid system of a photolithography equipment and a direct writing lithography equipment, in accordance with an embodiment of the disclosure.

### DETAILED DESCRIPTION

Panel based lithography involves lithography on large typically rectangular substrates. As these panel substrates grow in size and the patterned features shrink, it becomes more difficult to keep throughput (the pace at which these substrates are processed) at reasonable rates. Photolithography based systems can have large field sizes so that they can quickly expose large areas of the panel substrate. However, these photolithography systems have difficultly in keeping a large field size, while exposing small features. Direct write lithography systems can create small features, but are comparably very slow for throughput. In order to keep high throughput, but still have smaller patterned features, a hybrid approach is presented where a large field size photolithography is first used to pattern larger features on the substrate, then direct write lithography is used to pattern the smaller features on the substrate.

Advanced Packaging (AP) processes require fabrication of micron sized features such as redistribution layers (RDLs) (e.g., conductive traces or interconnects that electrically connect one part of the semiconductor package to another) and layers of vias (e.g., conduits that enable the conduction of electrical signals between layers of a device) on the substrate. This is particularly true for advanced integrated circuit substrates (AICS), in which AP lithography resolution requirements are expected to shrink below 1 μm line/space (L/S). In such cases, optical lithography (photolithography) methods with larger fields may not be able to provide effective resolution for larger imaging areas that exceeds 125 mm×125 mm. The present disclosure addresses this concern.

In general terms, the present disclosure relates to improving throughput of lithography at lower resolutions by combining photolithography with direct writing lithography in substrate fabrication.

A semiconductor wafer is generally a flat discoid object of varying diameter. Semiconductor wafers are generally formed of a semiconductor material such as silicon, gallium arsenide, and the like, though in some instances Glassell composite materials such as epoxy can be used. In some embodiments, the semiconductor wafer can include an orientation structure such as a notch, mark, flat or other structure. Such semiconductor wafers frequently have a diameter of between about 200 mm and about 300 mm, but other sizes of semiconductor wafers are also common.

A semiconductor panel is generally a flat object made of semiconductor materials, glass, or composite materials. Semiconductor panels typically have a rectangular or square shape and come in a variety of sizes, although there are common sizes referred to as “generations” with specific dimensions follow: Gen. 1:300×400 mm; Gen. 2:360×465 mm; Gen. 2.5:400×500 mm; Gen. 3:550×650 mm; Gen. 3.5:620×750 mm; Gen. 4:730×920 mm; Gen. 5:1100×1300 mm; Gen. 6:1500×1850 mm; Gen. 7:1870×2200 mm; Gen. 7.5:1950×2200 mm; and Gen. 8:2200×2500 mm. Advanced integrated circuit substrates (AICS) may have the following dimensions: 510×515 mm; or 600×600 mm. In some embodiments, the semiconductor panel can be in the form of a copper core laminate (CCL) panel, etc. In some embodiments, the semiconductor panel can be a glass panel substrate, or other panel constructed of soda-lime glass treated with one or more special coatings to improve the adhesion and uniformity of deposited materials.

A semiconductor substrate is a substrate that includes material such as a semiconductor, glass, or copper clad laminate, or any other material, such as a substrate of a semiconductor panel or a semiconductor wafer. Where some specific information specific to either a wafer or a panel, respectively, is to be related, the specific terms will be used. In some embodiments, either a wafer or a panel can serve as a base upon one or more layers of material are applied and processed to create a multilayered semiconductor substrate. For example, the one or more layers can include one or more redistribution layers, which may include conductive traces, interspaced between insulative, dielectric layers. Through holes can be defined in the wafer or a panel to enable communication between layers applied to opposing major surfaces of the wafer or a panel.

In some embodiments, the semiconductor panel can include an array of repeated functional units, each of which can represent a portion of a semiconducting substrate on which a given functional circuit is fabricated. For example, in one non-limiting example, the functional circuit can take the form of a central processing unit. In some embodiments, additional electrical components can be electrically coupled to the semiconductor panel to complete the functional unit. In other embodiments, the layered semiconductor panel itself can represent a completed functional unit.

Each of the functional units can then be cut from the semiconductor panel into (e.g., rectangular shaped) dies, wherein each die contains one copy of the functional circuit. To avoid damage to the dies, in some embodiments, a thin, non-functional spacing can be provided between dies, allowing for cutting (e.g., with a saw) of individual dies from a substrate without damaging the circuits. In this manner, a functional circuit can be batch manufactured on a single semiconductor substrate. Once cut into individual dies, the dies can be applied to a printed circuit board for use in electronics.

Photolithography refers to a technique used in substrate fabrication that comprises of transferring a pattern from a reticle onto a substrate coated with a light-sensitive material called photoresist. Photolithography involves directing a light source through the pattern containing reticle onto the photoresist coated substrate. The photoresist is further developed to reveal a patterned photoresist layer on the substrate, which acts as a stencil for subsequent etching or deposition steps, enabling the precise fabrication of intricate micron sized features. Photolithography is a useful step in high-volume manufacturing of integrated circuits, allowing for accurate patterning of larger features with resolution greater than 1.2 microns or 1 micron. The photolithography equipment can be photolithographic steppers (steppers) or scanners, used as part of in-line, panel-production equipment. The substrate can be, for example, an Advanced Integrated Circuit Substrates (AICS) panel or another type of panel or substrate, such as a glass panel. The panel may be, for example, a flat-panel display or another substrate type.

Direct writing lithography refers to a lithographic technique used in substrate fabrication where patterns are directly written onto the substrate without involving a reticle. Direct writing lithography comprises of directly focusing a beam of energy onto the substrate controlled by a computer subsystem. In this process, the substrate is coated with a resist material which alters its chemical composition when exposed to the energy beam. The process involves scanning the beam across the resist coated substrate in a controlled manner for writing the desired pattern onto the substrate. Types of direct writing lithography typically includes Laser Direct Imaging (LDI), Electron Beam Lithography, Focused Ion Beam Lithography, Direct Laser Writing, Dip Pen Nanolithography, Proton Beam Writing or Nanoimprint Lithography. The absence of a reticle makes direct writing lithography more flexible and precise for patterning submicron features (small dimension features) with resolution less than 1.2 microns.

As used herein, resist refers to a light-sensitive material applied to the substrate, prior to etching or deposition processes. Generally, resists are of two types, positive resist and negative resist. In positive resist, the areas exposed to light have higher solubility in the presence of developer solution, allowing them to be selectively removed to reveal the unexposed areas behind as a protective mask. In negative resist, the exposed areas have lesser solubility, and these areas remain after development, while the unexposed regions are removed, creating a desired pattern on the resist coated substrate. The development of resist involves applying a chemical developer to selectively remove either the exposed or unexposed portions of the resist, depending on its type. This process transfers the pattern from the reticle or direct writing equipment onto the substrate, enabling precise patterning of the micron-sized circuit features.

Etching refers to a technique used in lithography to transfer a pattern from the resist layer onto the substrate. Subsequent to resist development, etching is performed to selectively remove material from areas not protected by the resist using various techniques, such as wet etching (where a liquid chemical solution dissolves the exposed material) or dry etching (which involves the use of reactive gases or plasmas). An example of dry etching is Oxygen Reactive Ion Etching (O2 RIE), where oxygen plasma is used to etch away exposed areas, particularly in dielectric materials. Dry etching is a commonly opted etching method for transferring features and interconnect patterns onto the substrate beneath the resist layer in substrate fabrication applications.

Patterned features refer to Redistribution layer (RDL) lines, pads, and vias. The RDL lines are conductive traces utilized in advanced semiconductor packaging to redistribute electrical signals. The RDL lines are mainly made of metals like copper or aluminum. The metals are often combined with barrier layers like titanium or tantalum, as well as gold (Au) for high-reliability applications due to their corrosion resistance properties. The RDL (Redistribution Layer) lines are closely spaced, ranging from 0.1 to 30 microns, sometimes less than 2 microns to optimize interconnect density and facilitate efficient signal routing. Vias are vertical interconnects that pass through one or more Redistribution layer which acts as an electrical path between different layers of the advanced semiconductor package. The vias are used to interconnect RDL lines, for routing the electrical to external pins or other components. Vias in RDL are useful for enabling complex routing in advanced packaging technologies like 3D ICs or fan-out wafer-level packaging. In some embodiments, as per the present disclosure, when the RDL lines less than 1 um L/S, a damascene style architecture is used for both RDL and Via layers.

Stitching refers to the technique of merging multiple exposure fields to pattern a larger substrate, which exceeds the field size of the photolithography equipment. The photolithography equipment has the issue of smaller exposure fields making it difficult to pattern a large substrate in one shot. The stitching technique overcomes this issue by exposing the substrate in separate, non-overlapping regions and then precisely combining these regions ensuring alignment accuracy. The stitching process ensures that there are no gaps or misalignment between adjacent exposure shots, ensuring the integrity of the final pattern. Stitching is commonly used in smaller-field lithography systems to handle larger substrates in advanced manufacturing processes, such as semiconductor fabrication or display panel production.

Embodiments described herein may relate to a method, to improve the throughput of lithography for high-volume manufacturing applications. The method disclosed in the present disclosure, combines photolithography with direct writing lithography in low resolution applications of substrate fabrication. In an embodiment, the larger features are patterned using photolithography and the submicron features are patterned using direct writing lithography, ensuring that the low resolution challenges are effectively addressed without affecting stitching performance.

According to one aspect of the present disclosure, a method for improving throughput of lithography at lower resolutions by combining photolithography with direct writing lithography in substrate fabrication is disclosed. The method comprises exposing with photolithography equipment circuit patterns on a substrate of at least one-micron resolution and larger in a photoresist, wherein the field size is at least 50 mm by 50 mm. The method further comprises exposing with direct writing lithography equipment on the substrate circuit patterns less than at least one-micron resolution and smaller.

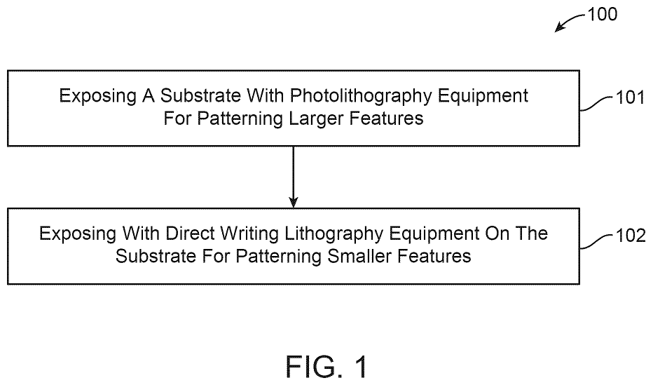

FIG. 1 depicts a method for improving throughput of lithography at lower resolutions, in accordance with the embodiments of the present disclosure. The method comprises of combining photolithography with direct writing lithography in substrate fabrication, by patterning larger features and smaller features separately. The method 100 comprises the step 102 of exposing a substrate with photolithography equipment for patterning larger features and the method 100 further comprises of the step 102 of exposing with Direct writing equipment on the substrate for patterning smaller features.

In an implementation embodiment, in accordance with the present disclosure, prior to the step 101 of exposing the substrate with photolithography equipment the method further comprises creating a CAD layout that includes both circuit patterns having at least one-micron resolution and also circuit patterns having resolution less than at least one-micron. The created CAD layout is further decoupled to separate the larger circuit pattern elements (or larger dimension features) having resolution larger than one-micron and the smaller circuit pattern elements (or smaller dimension features) with resolution less than one-micron. The method further comprises creating a reticle with the larger circuit pattern elements which are to be transferred onto the substrate during exposing with a photolithography equipment.

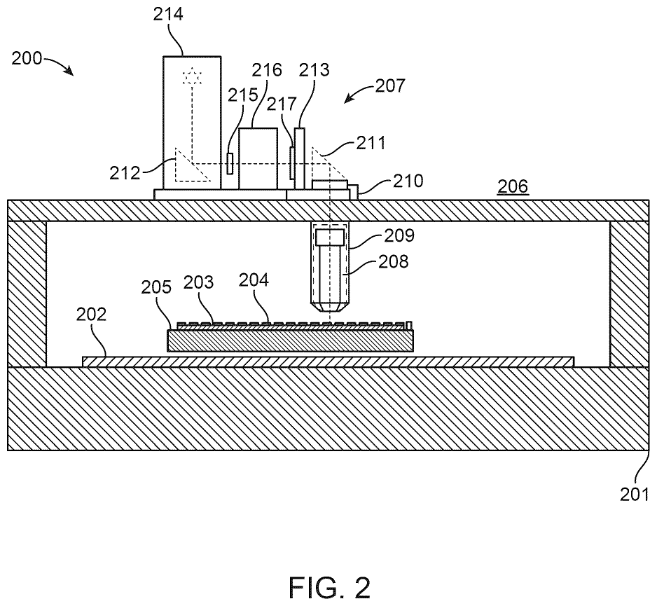

FIG. 2 schematically depicts photolithography equipment, in accordance with the embodiments of the present disclosure. The photolithography equipment 200 includes a base 201, which is typically a large block of finished granite that sits on isolation supports (not shown). The combination of the large mass of the base 201 and the design of the isolation supports provides isolation of the photolithography equipment 200 from floor vibrations. The isolation supports also prevent machine forces from getting into the factory floor and disturbing nearby machinery. The base 201 and isolation supports may be constructed from common commercial parts and materials.

On top of the base 201 is a large grid motor platen 202, which includes a matrix of soft iron teeth of about 1 mm square, separated in X and Y directions by a gap of about 1 mm. The gaps between the teeth are filled with non-magnetic material, usually epoxy. This surface is ground very flat, to tolerances of a few microns, to provide an air bearing quality surface. Flatness is also useful to control tip and tilt of a main X, Y, O stage 205, a possible source of Abbe offset errors in a stage interferometer system. The area covered by the grid motor platen 202 is large enough to allow the stage 205 to move to its desired positions. The travel area allows movement to a substrate 204 exchange position (at the system front) and throughout an exposure area. The travel area for the embodiment described herein correlates to the size of a substrate carried on the stage 205.

The stage 205 has within its body a number of forcer motors (not shown). These motors are arranged to drive the stage across the grid motor platen 202. Two motors are oriented to drive the stage 205 in an X-axis direction. Two additional motors are oriented at 90° to drive the stage 205 in a Y-axis direction. Either or both pairs of motors may be driven differentially to provide small rotation motion (θ). In this manner, the stage 205 may be controlled to move in a very straight line even though the tooth pattern in the grid motor platen 202 may not be straight. As per present disclosure, the stage 205 has a chuck 203 mounted thereon. The illustrated chuck 203 has a form factor adapted to support a substrate 204 that is a panel P. Furthermore, the chuck 203 may have substituted therefore different numbers or types of chucks or top plates adapted to hold different substrates 204 such as silicon wafers.

A stiff bridge structure 206 supports a projection camera 207 above the stage 205. The projection camera 207 has a projection lens 208, of approximately 2× (i.e., two times) reduction, mounted in a lens housing 209. The lens housing 209 is mounted on two Z-axis (vertical) air bearings, not shown. These air bearings may be commercially purchased and can be a box journal style, which are very stiff. This Z-axis motion is used to move the lens housing 209 and projection lens 208 up and down over small distances used for focus. The projection lens 208 can be telecentric at its image side, so that small changes in focus do not cause image size or image placement errors. Note that other optical arrangements and magnifications are contemplated and the optical arranged described herein is not to be taken as limiting.

The projection lens housing 209 has an individual, real-time, auto-focus sensor (not shown) attached to its bottom. These sensors use simple optics to transform a laser diode light source into a focused slit of light at a substrate 204. Some of the light from this slit reflects off the substrate 204 and is captured by a receiving side of the real-time auto-focus sensor. The reflected slit light is imaged by the receiving optics onto a linear CCD array (not shown). Image processing software is used to locate the image of the reflected slit on the CCD array. Any shift in the position of the image of the reflected slit is then used to control Z-axis drive 210 for projection camera 207, until the position of the image on the CCD array is restored. In this manner, the “focus” of projection camera 207 is maintained at a constant gap. During the construction of a lithography system, the motion of the Z-axis in micrometers is used to determine the motion of the image on the CCD array in pixel units. This calibration permits conversion of subsequent focus offsets to be implemented as pixel offsets in the Z-axis focus control system.

Attached to the top of the lens housing 209 is a fold mirror 211. This mirror 211 puts the remainder of the projection camera 207 off to the left side in the FIG. 2. In this embodiment, the projection lens 208 is designed to have a long working distance at its object side to permit use of the fold mirror 211. Note that by the omission of fold mirrors from the projection camera 207, a straight optical path may be achieved. Fold mirrors having different orientations may also be used to further form the optical path of the projection camera 207 to meet whatever space requirements that exist.

Projection camera 207 has its own 6-axis reticle chuck 213, which holds a reticle 217 that includes the pattern having the large features which are being imaged onto the substrate 204. The reticle 217 may be referred to as an image source. It should be understood that other devices may also be used as image sources, such as a multi-mirror light valve or an LCD light valve that dynamically generates a mask.

Illumination for the photolithography exposure is provided by a lamp house 214 that encloses a mercury lamp that outputs about 3500 watts' power. The light within the lamp house 214 is collected, focused, and filtered, and then exits the lamp house 214 near a shutter 215. The lamp house 214 further includes a fold mirror 212 that allows the optical path of the projection camera 207 to be made more compact. The folded arrangement of the projection camera 207 as illustrated in FIG. 2 is one configuration of many that can be or are commonly used.

When the shutter 215 is opened, light from the lamp house 214 passes through a condenser lens assembly 216, through the reticle 217, through projection lens 208, and exposes the substrate 204 with large feature circuit patterns imposed by the reticle 217. As is well understood, the substrate 204 is coated with a photo-sensitive resistive coating. A dose sensor may be part of the shutter 215, where the pattern projected by camera 207 is well aligned with intended circuit elements to be patterned on the substrate 204.

As per the present disclosure, the method comprising, exposing of the larger circuit pattern elements onto the substrate, includes calibrating the photolithography equipment to a grid such that nominal stitching performance is optimized. The reticle design is such that the substrate is exposed with stitching reticle designs that extend beyond the field size of the photolithography equipment. The reticle stitch is designed in way that stitch boundary is terminated to provide a small gap, 5 to 10 μm between the exposure fields. Furthermore, the photolithography equipment resolution is 1.2 microns and larger or 1 micron and larger.

In a one embodiment of the method as per the present disclosure, a thin layer of hard mask material is deposited onto the substrate for defining the RDL and vias structures, wherein the hard mask materials are typically Titanium (Ti) or Copper (Cu) and the substrate is a glass panel with organic dielectric material. The substrate is further coated with a photoresist material, and exposed to project the circuit pattern elements with resolution larger than at least one-micron resolution onto the photoresist. In an embodiment, the photoresist material may be any suitable photosensitive material, such as an i-line resist. The photoresist pattern is further transferred onto the hard mask material on the substrate using various etching methods, such as wet etching and dry etching. Subsequent to etching of the hard mask, the remaining photoresist material is stripped away, resulting in a substrate patterned with larger circuit pattern elements.

In accordance with an embodiment of the present disclosure, a method for improving throughput of lithography at lower resolutions utilizes combining photolithography with direct writing lithography in substrate fabrication, comprises separating circuit pattern elements that are smaller than one micron from a CAD layout to create instructions for the direct writing lithography equipment to pattern smaller elements on the substrate. The direct writing lithography for example, includes at least one of Laser Direct Imaging (LDI), Electron Beam Lithography, or Focused Ion Beam Lithography.

In one embodiment, the direct writing lithography equipment is an electron beam lithography equipment with a resolution of less than 1 micron, sometimes going down to 10 nanometers. In some embodiments, the circuit patterns less than at least one-micron resolution and smaller, are transferred onto the substrate by exposing with the electron beam lithography equipment. The e-beam lithography equipment helps in achieving high resolution and is used to achieve accuracy while patterning intricate details onto the substrate.

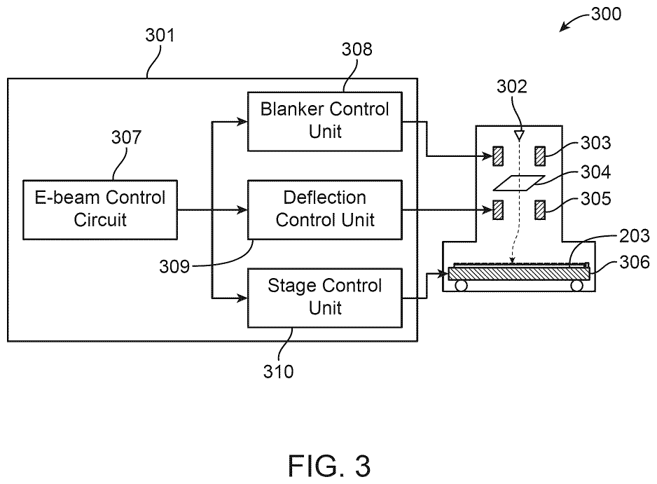

FIG. 3, schematically depicts a direct write lithography such as an electron beam (or e-beam) lithography equipment, in accordance with embodiments of the present disclosure. The electron beam lithography equipment 300 comprises an electron source (electron gun) 302 that generates a focused electron beam. The electron source 302 is generates an energy controlled electron beam, a tungsten Schottky emitter which is operated a few degrees below its normal operating temperature for reducing the energy spread of the electron beam generated. The electron beam lithography equipment 300 further comprises blanker electrodes 303 which precisely controls the exposure, by modulating the electron beam to turn off and on, an aperture 304 which shapes the generated electron beam and deflection electrodes 305 which deflects the electron beam generated by the electron source 302. The electron beam lithography equipment 300 further comprises a stage 306 fold holding the substrate 313 and is movable in X and Y directions, during the e-beam lithography process.

The functioning of the e-beam lithography equipment 300 is controlled by a computer subsystem 301. The computer subsystem 301 comprises, an e-beam control circuit 307 which receives an e-file having the smaller features and controls the patterning of the substrate based on these features. The computer subsystem 301 further comprises a blanker control unit 308, deflection control unit 309 and a stage control unit 310. As per the present disclosure, the blanker control unit 308 regulates the irradiation time by controlling the timing of the electron beam during each exposure shot using the blanker electrodes 303. The deflection control unit 309 controls the shape and irradiation position of the electron beam during the exposure shot. The deflection electrodes 305 is adjusted by the deflection control unit 309 to direct the generated e-beam onto the exact position on the substrate 313 while maintaining the desired shape. The stage control unit 310 controls the position and movement of the stage 306 during e-beam lithography process.

Prior to exposing the substrate with e-beam, a thin layer of e-beam resist is applied on the substrate, wherein the resist is sensitive to electrons. The e-beam resist may be a positive or negative resist, chosen based on the application and is applied using spin-coating to achieve a uniform coat. The electron beam from the electron source 302 is directed to precise locations on the resist coated substrate using lenses and apertures. The electron beam is then scanned across the resist-coated substrate controlled by the computer subsystem. In some embodiments, the scanning method may be a raster scanning, where the scanning movement is in back-and-forth manner or a vector scanning, where the e-beam directly moves to the precise points with optimized speed and resolution. The electron beam scanning, alters the chemical structure of the e-beam resist, thereby creating the desired pattern on the resist-coated substrate. The electron beam movement across the substrate is based on a computer-generated file, that defines the pattern to be transferred onto the substrate. Subsequently, the resist coated substrate is developed and the e-beam resist is etched to transfer the pattern onto the substrate. In some embodiments, the same resist can be used for the photolithography and the direct write lithography.

In some embodiments of the present disclosure, a method for improving throughput of lithography at lower resolutions by combining photolithography with electron beam lithography in substrate fabrication comprises separating circuit pattern elements that are smaller than one micron from a CAD layout to create instructions for the e-beam equipment to pattern smaller elements on the substrate. As per the present disclosure, an e-beam (electron-beam) file is generated which includes the smaller circuit pattern elements to be patterned onto the substrate. The generated e-beam file is received by the e-beam control circuit 307 present in computer subsystem 301 to determine the scanning movement of the e-beam lithography equipment.

In a further implementation embodiment as per the present method, the substrate is coated with an electron beam-sensitive resist and exposed with the electron beam lithography equipment to transfer the smaller circuit pattern elements less than at least one-micron resolution onto the e-beam resist coated substrate. The computer subsystem controls the scanning movement of the e-beam lithography equipment based on the e-beam filed generated and the desired pattern is created on the e-beam resist coated substrate. The smaller dimension features are patterned onto the e-beam resist, such that it aligns to a latent image in the photoresist, created previously during photolithography. Optionally, the larger circuit pattern elements created by the photolithography equipment are transferred to a hard mask prior to e-beam lithography.

The electron beam lithography equipment in an embodiment utilizes an adaptive patterning technique which dynamically adjusts the patterning of the smaller circuit pattern elements (smaller dimension features) based on the previously patterned larger dimension features using the photolithography, thereby integrating the smaller features around the larger dimension features to ensure continuity. As per the present disclosure, the e-beam control circuit 307 receives the e-file comprising the smaller features to be patterned onto the substrate 204, using which the e-beam control circuit 307 regulates on the position, irradiation time and shape of the generated electron beam, by outputting a control signal to the blanker control unit 308, deflection control unit 309 and stage control unit 310. The e-beam lithography equipment 300 pattern the smaller features onto the substrate corresponding to the already patterned larger features (using photolithography), thereby achieving adaptive patterning. The adaptive patterning aids in overcoming the alignment errors and gaps typically caused by stitching.

Subsequent to patterning the smaller circuit pattern elements onto the e-beam resist coated substrate, the e-beam resist is developed to remove the exposed or unexposed areas, depending on the type of e-beam resist used, creating the desired pattern on the substrate. This is followed by dry or wet etching to obtain the pattern on the substrate lying beneath the resist, subsequent to which the remaining resist is stripped away to reveal the desired pattern on the substrate.

In an alternate embodiment, the direct writing lithography may be a Laser Direct Imaging (LDI) system, wherein the smaller dimension features are transferred onto the substrate using laser beams. As per the present disclosure, the LDI system utilizes a computer-generated file comprising the smaller circuit pattern elements. These smaller dimension features are patterned onto the substrate which is coated with a thin layer of resist material sensitive to laser beam. The laser beam is directed onto the resist-coated substrate, exposing the resist to create the pattern defined by the computer-generated file on the resist-coated substrate. This is followed by developing and etching processes, revealing the desired pattern on the substrate.

In accordance with the present disclosure, the exposing by photolithography equipment provides defined stitch boundaries with a spacing of at least 5 μm, or at least 10 μm between adjacent exposure shots, and exposing with direct writing lithography equipment on the substrate circuit patterns to stitch together the exposure shots by the photolithography equipment. The defined spacing between the stitch boundaries helps in minimizing overlapping or misalignment errors, resulting in the overall accuracy of the patterning process. By leaving a stitching gap (of around 5-10 microns), yield can be increased by ensuring good overlay and alignment through the use of direct write lithography to stitch together the various shots.

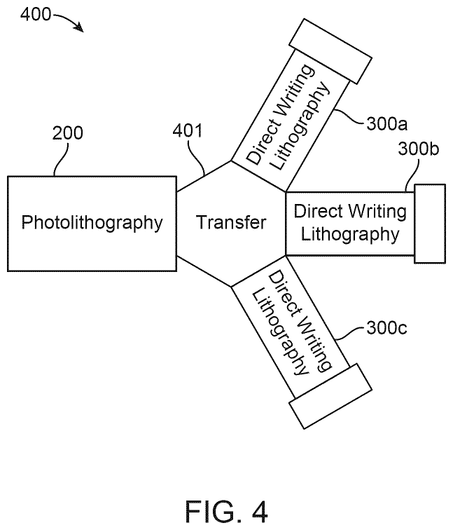

FIG. 4 schematically depicts a hybrid system 400 in conjunction with which the method 100 of FIG. 1 can be implemented, according to an embodiment of the present disclosure. The hybrid system (or otherwise a tool) as shown in 400, comprises of the photolithography equipment 200, which performs the patterning of the larger circuit pattern elements onto the substrate 204 and at least one direct writing lithography equipment 300 which performs the patterning of the smaller circuit pattern elements onto the substrate 204. The photolithography equipment 200 is faster, as it can expose large field sizes quickly, which has resolution higher than one-micron, whereas the direct writing lithography equipment 300 offers a lesser speed as it patterns the smaller circuit pattern elements, which has resolution less than one-micron. This disparity in speed affects the final throughput of the hybrid system, which has been addressed by configuring the photolithography equipment 200 to work in conjunction with a plurality of direct writing lithography equipment's for example, 300a, 300b and 300c.

In a further detailed implementation referring to FIG. 4, the hybrid system 400 comprises of a transfer mechanism 401 for transferring the substrate from the photolithography equipment 200 to the direct writing lithography equipment. As per the present disclosure, the at least one direct writing lithography equipment(s) 300a, 300b and 300c works in conjunction to keep up with the throughput of the photolithography equipment 200. Subsequent to patterning the larger features on the substrates using photolithography equipment 200, the transfer mechanism 401 transfers the substrates to one of the plurality of direct writing lithography equipment. In some embodiments as per the present disclosure, the direct writing lithography equipment 300a, 300b and 300c works individually on separate substrates to reduce the speed disparity between the photolithography patterning and the direct writing lithography patterning.

In some embodiments of the present disclosure, the transfer mechanism 401, is an automated mechanism for precise handling and efficient transfer of substrates between different lithography equipment. As per present disclosure, the transfer mechanism 401 is configured to transfer the substrates from the photolithography equipment 200 to one of the plurality of direct writing lithography equipment 300a, 300b and 300c. The transfer mechanism 401, uses a robotic arm, equipped with end-effectors configured to securely grip and transfer the substrate which is patterned with the larger features using the photolithography equipment 200. The robotic arm is controlled by a software, which coordinates the accurate positioning and alignment of the substrates to be patterned with the plurality of direct writing lithography equipment's. The transfer mechanism 401, aids in optimizing throughput and compensating for the speed disparity between the photolithography and the direct writing lithography equipment.

In an embodiment referring to FIG. 4, the direct writing lithography equipment 300a, 300b and 300c are electron beam (e-beam) lithography equipment, which works in conjunction with the photolithography equipment 200. Subsequent to patterning the larger circuit pattern elements having resolution higher than one-micron using photolithography equipment 200, the substrates are transferred using the transfer mechanism 401, to the direct lithography equipment 300a, 300b and 300c for patterning the smaller circuit pattern elements having resolution less than one-micron. The transfer mechanism 401 incorporates a robotic arm, configured to precisely transfer and align the substrates on the e-beam lithography equipment.

In some embodiments, the hybrid system described herein may be employed to perform the method disclosed in various other configurations and not limited the embodiments set forth herein.

In a beneficial embodiment of the present disclosure, combining photolithography with direct writing lithography in substrate fabrication at lower resolutions, helps in overcoming the issues caused by stitching in photolithography where the field size is at least 50 mm by 50 mm. As per the present disclosure, utilizing Direct writing lithography to pattern the smaller dimension features in alignment with the large dimension features, previously created using photolithography, thereby ensuring accurate integration and continuity of the patterns. This combined approach is beneficial in reducing misalignment and providing a reliable method for obtaining high-resolution features on the substrate in high-volume manufacturing (HVM) applications. Additionally, the method as per the present disclosure allows for significant increase in production efficiency without compromising resolution quality, and simultaneously catering to the evolving needs of advanced semiconductor fabrication.

The embodiments described herein may be employed using software, hardware, or a combination of software and hardware to implement and perform the systems and methods disclosed herein. Although specific devices have been recited throughout the disclosure as performing specific functions, one of skill in the art will appreciate that these devices are provided for illustrative purposes, and other devices may be employed to perform the functionality disclosed herein without departing from the scope of the disclosure. In addition, some aspects of the present disclosure are described above with reference to block diagrams and/or operational illustrations of systems and methods according to aspects of this disclosure. The functions, operations, and/or acts noted in the blocks may occur out of the order that is shown in any respective flowchart. For example, two blocks shown in succession may in fact be executed or performed substantially concurrently or in reverse order, depending on the functionality and implementation involved.

This disclosure describes some embodiments of the present technology with reference to the accompanying drawings, in which only some of the possible embodiments were shown. Other aspects may, however, be embodied in many different forms and should not be construed as limited to the embodiments set forth herein. Rather, these embodiments were provided so that this disclosure was thorough and complete and fully conveyed the scope of the possible embodiments to those skilled in the art. Further, as used herein and in the claims, the phrase “at least one of element A, element B, or element C” is intended to convey any of: element A, element B, element C, elements A and B, elements A and C, elements B and C, and elements A, B, and C. Further, one having skill in the art will understand the degree to which terms such as “about” or “substantially” convey in light of the measurement techniques utilized herein. To the extent such terms may not be clearly defined or understood by one having skill in the art, the term “about” shall mean plus or minus ten percent.

Although specific embodiments are described herein, the scope of the technology is not limited to those specific embodiments. Moreover, while different examples and embodiments may be described separately, such embodiments and examples may be combined with one another in implementing the technology described herein. One skilled in the art will recognize other embodiments or improvements that are within the scope and spirit of the present technology. Therefore, the specific structure, acts, or media are disclosed only as illustrative embodiments. The scope of the technology is defined by the following claims and any equivalents therein.

What is claimed is:

1. A method for improving throughput of lithography at lower resolutions by combining photolithography with direct writing lithography in substrate fabrication comprising:
exposing with photolithography equipment circuit patterns on a substrate of at least one-micron resolution and larger in a photoresist, wherein a field size of the photolithography equipment is at least 50 mm by 50 mm; and
exposing with direct writing lithography equipment on the circuit patterns on the substrate less than at least one-micron resolution and smaller.

2. The method of claim 1, wherein the substrate is a glass panel.

3. The method of claim 1, wherein the resolution is at least 1.2 microns and larger for the photolithography equipment and the resolution is at least 1.2 microns and lower for direct writing lithography equipment.

4. The method of claim 1, wherein the exposing by photolithography equipment provides defined stitch boundaries with a spacing of at least 5 μm, between adjacent exposure shots, and exposing with direct writing lithography equipment on the substrate circuit patterns to stitch together the exposure shots by the photolithography equipment.

5. The method of claim 1, wherein the circuit patterns includes redistribution lines (RDL), pads, and vias.

6. The method of claim 1, wherein the direct writing lithography includes at least one of Laser Direct Imaging (LDI), Electron Beam Lithography, and Focused Ion Beam Lithography.

7. The method of claim 1, wherein the direct writing lithography utilizing an adaptive patterning technique, dynamically adjusts the circuit patterning, based on previously patterned larger dimension features, thereby integrating smaller features around the larger dimension features to ensure continuity.

8. The method of claim 1, further comprising separating circuit pattern elements that are larger than one micron from a CAD layout and creating a reticle with these larger features.

9. The method of claim 8, further comprising separating circuit pattern elements that are smaller than one micron from a CAD layout to create instructions for the direct writing lithography equipment to pattern smaller elements on the substrate.

10. A lithography system for improving throughput of lithography at lower resolutions by combining photolithography with direct writing lithography in substrate fabrication comprising:
photolithography equipment configured to expose a circuit pattern on a substrate of at least one-micron resolution and larger in a photoresist, wherein a field size of the photolithography equipment is at least 50 mm by 50 mm;
a plurality of direct writing lithography equipment on the substrate to expose circuit patterns less than at least one-micron resolution and smaller; and
a transfer system that passes a substrate from the photolithography equipment to one of the plurality of direct writing lithography equipment.

11. The method of claim 1, wherein the substrate is a glass panel.

12. The system of claim 10, wherein the resolution is at least 1.2 microns and larger for the photolithography equipment and the resolution is at least 1.2 microns and lower for direct writing lithography equipment.

13. The system of claim 10, wherein the photolithography equipment provides defined stitch boundaries with a spacing of at least 5 μm, between adjacent exposure shots, and the direct writing lithography equipment exposes on the substrate circuit patterns to stitch together the exposure shots by the photolithography equipment.

14. The system of claim 10, wherein the circuit patterns includes redistribution lines (RDL), pads, and vias.

15. The system of claim 10, wherein the direct writing lithography includes at least one of Laser Direct Imaging (LDI), Electron Beam Lithography, and Focused Ion Beam Lithography.

16. The system of claim 10, wherein the direct writing lithography utilizing an adaptive patterning technique, dynamically adjusts the circuit patterning, based on previously patterned larger dimension features, thereby integrating smaller features around larger dimension features to ensure continuity.
